(19) United States
(12) Patent Application Publication
(10) Pub. No.: US 2024/0339814 A1
(43) Pub. Date: Oct. 10, 2024

(54) Vertical Cavity Surface-Emitting Laser with Independent Definition of Current and Light Confinement

(71) Applicant: II-VI Delaware, Inc., Wilmington, DE (US)

(72) Inventors: Stefano Tirelli, Zurich (CH); Eimantas Duda, Adliswil (CH); Antoine Pissis, Zurich (CH); Evgeny Zibik, Zurich (CH); Wolfgang Kaiser, Zurich (CH)

(21) Appl. No.: 18/131,571

(22) Filed: Apr. 6, 2023

(51) Int. Cl. H01S 5/183

(52) U.S. Cl. CPC H01S 5/1833; H01S 5/18311

(57) ABSTRACT

A Vertical Cavity Surface-Emitting Laser has a body including a vertical stack of semiconductor layers one on top of the other including a current confinement layer having an area of low resistance to current flow defined by an area of high resistance to current flow, whereupon vertical current flow in the stack of semiconductor layers is directed by the area of high resistance to current flow of the current confinement layer through the area of low resistance to current flow of the current confinement layer. A separate light confinement layer is disposed below or above the current confinement layer. The light confinement layer includes one or more protrusions or recesses disposed below or above the area of low resistance to current flow of the current confinement layer.

### BACKGROUND

### 1. Field

The present disclosure describes Vertical Cavity Surface-Emitting Lasers (VCSELs) that include optical mode selection or optical confinement separate from current confinement.

### 2. Description of Related Art

Heretofore, VCSELs with oxide apertures provided guided waveguides with effective refractive index contrast of about 1-2%, thus efficiently confining the optical modes. In these prior art VCSELs, oxide apertures are used to define both the current confinement as well as the index or light confinement. When single mode behavior is required, the oxide aperture needs to be reduced to 4 um or below, which proves challenging to be done reproducibly.

Additional mode selection elements on the top of the VCSEL device may be used to provide mode selectivity. In one example, a small metal aperture may be introduced on top of the VCSEL device to filter the unwanted higher order modes. (See Ueki et al., “Single-Transverse-Mode 3.4-mW Emission of Oxide-Confined 780-nm VCSELs,” IEEE Photonics Technology. Letters, vol. 11, no. 12, pp. 1539-1541, 1999). In another example, a “mode-filtering” approach may implement a surface relief on the top surface of the VCSEL device within the emission area. With this technique, a VCSEL with up to 6.5 mW of single mode power was reported. (See Haglund et al. “High-Power Single Transverse and Polarization Mode VCSEL for Silicon Photonics Integration”. Vol. 27, No. 13, Optics Express 18892, 2019). Yet another example utilized an impurity-induced disorder of the top Distributed Bragg Reflector (DBR) mirror to reduce reflectivity and, hence, suppress higher order modes. This resulted in a VCSEL emitting ˜10 mW of single mode power (See Su et al., “High-power single-mode vertical-cavity surface-emitting lasers using strain controlled disorder-defined apertures”, Appl. Phys. Lett. 119, 241101, 2021). These methods all rely on introducing optical losses for high order modes.

Yet another example customized the mode shape by engineering the index confinement, e.g., by etching a photonic-crystal-like structure in the epilayer. (See Siriani et al., “Mode Control in Photonic Crystal Vertical-Cavity Surface-Emitting Lasers and Coherent Arrays”, IEEE Journal of Selected Topics in Quantum Electronics, Vol. 15, No. 3, pp. 909-917, 2009) This latter approach relies on a different principle, but losses arising from the roughness of the vertical etching of deep holes are still introduced. Additionally, the geometries that may be implemented with this approach are limited. Another limitation to this approach, like with conventional oxide VCSELs, is that the regions that define the current confinement also define the profile of the index or light guiding region.

Mode control in VCSELs is crucial for many applications. In some cases, single or few-modes operation is beneficial and sometimes even necessary. This is the case of, e.g., optical communication, where the presence of many optical modes impairs the relative noise or increases optical dispersion because of the linewidth broadening. In other cases, such as when a VCSEL is used as a projecting light source, for example for sensing application, a higher-mode order operation is beneficial, in order to have a uniform energy distribution across the emission angle. In both cases, the freedom of defining the optical mode may be an asset in attaining the required performance.

In conventional oxide-aperture VCSELs, the oxide aperture defines the current-confinement as well as the index-confinement region. While the process is straightforward, there are limitations to this approach: as not being able to define very small mode volumes, for example to promote single-mode operation, or having variations on the oxidation depth, which also impacts the mode shape and the yield across the wafer. In addition, the magnitude of the refractive index contrast between the light-emitting region and the surroundings is essentially fixed by the difference between the refractive indexes of the oxidized and the unoxidized oxide aperture formed in a layer of AlGaAs, which is a commonly used material to fabricate oxide aperture VCSELs.

It would therefore be desirable to provide VCSELs having independent definition of index or light and current confinement.

### SUMMARY

Disclosed herein are VCSELs where index, mode, or light confinement and current confinement are independently defined, e.g., via an overgrowth process that provides freedom in the definition of the index or light guiding geometries, whereupon mode control is addressed in an extremely flexible way. In an example, a patterned mode selection layer, herein also referred to as a light confinement layer, is introduced during growth of the epitaxial layer used to form the patterned mode selection layer. This layer is then patterned lithographically, then the rest of the epitaxial growth is carried out, and the remainder of the VCSEL is finally fabricated through a conventional fabrication process. Herein, when used with the term “confinement”, the terms “index”, “mode”, “light”, and “optical” may be used interchangeably.

In the thus fabricated VCSEL, current confinement and optical confinement may be completely independent, allowing for wider design freedom and design robustness. The patterning of the mode or light confinement layer allows the definition of both the mode size, mode order, and the index contrast of the optical emission. With an appropriately engineered design, e.g., by creating an oxide aperture wider than the mode confinement region, changes in the current confinement layer will not directly affect the optical mode shape, thus leading to robust mode shaping. This also enables an additional degree of freedom in the design, with the only drawback being the addition of one or more additional lithography steps and an overgrowth process. The rest of the VCSEL fabrication process may remain unchanged, thus ensuring compatibility with existing fabrication techniques.

More specifically, disclosed herein is a VCSEL comprising a body comprising a vertical stack of semiconductor layers one on top of the other, wherein the stack of semiconductor layers comprises: a current confinement layer including an area of low resistance to current flow defined by an area of high resistance to current flow, whereupon vertical current flow in the stack of semiconductor layers is directed by the area of high resistance to current flow of the current confinement layer through the area of low resistance to current flow of the current confinement layer. A light confinement layer is disposed or positioned below or above the current confinement layer. The light confinement layer includes a protrusion or a recess disposed or positioned below or above the area of low resistance to current flow of the current confinement layer.

### BRIEF DESCRIPTION OF THE DRAWING(S)

FIG. 1 is an enlarged schematic side view of an example VCSEL in accordance with the principles of the present disclosure comprising a light confinement layer including a protrusion or bump, an intermediate layer above the light confinement layer, and a current confinement layer above the intermediate layer;

FIGS. 2A-2B are isolated schematic side and plan views of the example light confinement layer, intermediate layer, and current confinement layer of the VCSEL shown in FIG. 1;

FIGS. 3A-3B are isolated schematic side and plan views of another example light confinement layer, intermediate layer, and current confinement layer that may be used with the VCSEL shown in FIG. 1;

FIGS. 4A-4B are isolated schematic side and plan views of another example light confinement layer, intermediate layer, and current confinement layer that may be used with the VCSEL shown in FIG. 1;

FIGS. 5A-5B are isolated schematic side and plan views of another example light confinement layer, intermediate layer, and current confinement layer that may be used with the VCSEL shown in FIG. 1;

FIG. 6A is an isolated schematic plan view of another example light confinement layer, intermediate layer, and current confinement layer that may be used with the VCSEL shown in FIG. 1, wherein the protrusion or bump is in the form of circular stair-steps or a circular stair-case comprising a series of steps that increase or decrease in height as the steps wind around a central axis;

FIG. 6B is an isolated schematic plan view of another example light confinement layer, intermediate layer, and current confinement layer that may be used with the VCSEL shown in FIG. 1, wherein the protrusion or bump is irregular shaped and comprises a plurality of regions of different heights;

FIG. 7 is an enlarged schematic side view of another example VCSEL in accordance with the principles of the present disclosure comprising a light confinement layer including a recess or cavity, an intermediate layer above the light confinement layer, and a current confinement layer above the intermediate layer;

FIGS. 8A-8B are isolated schematic side and plan views of the example light confinement layer, intermediate layer, and current confinement layer of the VCSEL shown in FIG. 7;

FIGS. 9A-9B are isolated schematic side and plan views of another example light confinement layer, intermediate layer, and current confinement layer of the VCSEL shown in FIG. 7;

FIGS. 10A-10B are isolated schematic side and plan views of another example light confinement layer, intermediate layer, and current confinement layer of the VCSEL shown in FIG. 7;

FIGS. 11A-11B are isolated schematic side and plan views of another example light confinement layer, intermediate layer, and current confinement layer of the VCSEL shown in FIG. 7;

FIG. 12A is an isolated schematic plan view of another example light confinement layer, intermediate layer, and current confinement layer that may be used with the VCSEL shown in FIG. 7, wherein the recess or cavity is in the form of circular stair-steps or a circular stair-case comprising a series of steps that increase or decrease in height as the steps wind around a central axis;

FIG. 12B is an isolated schematic plan view of another example of the light confinement layer, the intermediate layer, and current confinement layer of the example VCSEL shown in FIG. 7, wherein the recess or cavity is irregular shaped and comprises a plurality of regions of different heights;

FIG. 13 is an enlarged schematic side view of another example VCSEL in accordance with the principles of the present disclosure comprising a light confinement layer including a protrusion or bump and a current confinement layer above the light confinement layer, but excluding the intermediate layer shown in FIG. 1;

FIG. 14 is an enlarged schematic side view of another example VCSEL in accordance with the principles of the present disclosure comprising a light confinement layer including a recess or cavity and a current confinement layer above the light confinement layer, but excluding the intermediate layer shown in FIG. 7;

FIG. 15 is an enlarged schematic side view of another example VCSEL in accordance with the principles of the present disclosure comprising a light confinement layer including a protrusion or bump, an intermediate layer including an optional protrusion or bump above the protrusion or bump of the light confinement layer, and a current confinement layer including an optional protrusion or bump above the protrusion or bump of the intermediate layer;

FIG. 16 is an enlarged schematic side view of another example VCSEL in accordance with the principles of the present disclosure comprising a light confinement layer including a recess or cavity, an intermediate layer including an optional recess or cavity above the recess or cavity of the light confinement layer, and a current confinement layer including an optional recess or cavity above the recess or cavity of the intermediate layer;

FIG. 17 is an enlarged schematic side view of an example VCSEL in accordance with the principles of the present disclosure comprising a current confinement layer, an intermediate layer above the current confinement layer, and a light confinement layer, including a protrusion or bump, above the intermediate layer;

FIG. 18 is an enlarged schematic side view of an example VCSEL in accordance with the principles of the present disclosure comprising a current confinement layer, an intermediate layer above the current confinement layer, and a light confinement layer, including a recess or cavity, above the intermediate layer;

FIG. 19 is an enlarged schematic side view of an example VCSEL in accordance with the principles of the present disclosure comprising a current confinement layer and a light confinement layer, including a protrusion or bump, above current confinement layer, but excluding the intermediate layer shown in FIG. 17; and

FIG. 20 is an enlarged schematic side view of an example VCSEL in accordance with the principles of the present disclosure comprising a current confinement layer and a light confinement layer, including a recess or cavity, above current confinement layer, but excluding the intermediate layer shown in FIG. 18.

### DESCRIPTION

Various non-limiting examples will now be described with reference to the accompanying figures where like reference numbers correspond to like or functionally equivalent elements.

For purposes of the description hereinafter, terms like “end,” “upper,” “lower,” “right,” “left,” “vertical,” “horizontal,” “top,” “bottom,” “lateral,” “longitudinal,” and derivatives thereof shall relate to the example(s) as oriented in the drawing figures. However, it is to be understood that the example(s) may assume various alternative variations and step sequences, except where expressly specified to the contrary. It is also to be understood that the specific example(s) illustrated in the attached drawings, and described in the following specification, are simply exemplary examples or aspects of the disclosure. Hence, the specific examples or aspects disclosed herein are not to be construed as limiting.

With reference to FIG. 1, one non-limiting embodiment or example VCSEL in accordance with the principles of this disclosure comprises a body 2 including a vertical stack of semiconductor layers 4, such as, for example, without limitation, layers of GaAs, AlGaAs, AlInGaAsP, InGaAs, InP, or InAlGaN, grown or deposited one atop of each other by, for example, chemical vapor deposition (CVD) or molecular beam epitaxy (MBE). The stack of semiconductor layers 4 may include, from a bottom to a top of body 2, a substrate 6, a lower Distributed Bragg Reflection (DBR) mirror layer 8, a cavity layer 10 including an active region 12, a light confinement layer 14, an intermediate layer 16, a current confinement layer 18, and an upper DBR mirror layer 20. The continued growth of the upper DBR mirror layer 20 may form or define an optional cap layer as part of the upper DBR mirror layer 20.

Herein, when used in connection with DBR mirror layers 8 and 20, the terms “first”, “lower”, “second”, and “upper” are used strictly for the purpose of description, illustration and clarity and are not to be construed in a limiting sense. Moreover, the terms “lower” and “upper”, when used in connection with DBR mirror layers 8 and 20, are used strictly in connection with the orientations shown in the figures and are not to be construed in a limiting sense. Furthermore, herein, one of the DBR mirror layers may be referred to as a first DBR mirror layer and the other DBR mirror layer may be referred to as a second DBR mirror layer strictly for the purpose of description, illustration and clarity and is not to be construed in a limiting sense.

A first electrical contact 24 may be positioned in electrical contact with a topside of the upper DBR mirror layer 20. In an example, the first electrical contact 24 may be ring shaped including an opening O for the passage of light generated by the operation of the VCSEL. However, this is not to be construed in a limiting sense since it is envisioned that the first electrical contact 24 may be any suitable and/or desirable shape or geometry that permits light generated by the operation of the VCSEL (discussed hereinafter) to exit the topside of the upper DBR mirror layer 20.

A second electrical contact 25 may, in one example, be positioned in electrical contact with a bottom side of the substrate layer 6 opposite the lower DBR mirror layer 8. In another example, the second electrical contact 25, shown in phantom in FIG. 1, may be positioned on a side of the body 2 in electrical contact with substrate 6. Herein, the terms “first” and “second”, when used in connection with contacts 24 and 25, are used strictly for the purpose of description, illustration and clarity and are not to be construed in a limiting sense.

In yet another example, also shown in phantom in FIG. 1, the second electrical contact 25 may be positioned on the topside of the upper DBR mirror layer 20, e.g., proximate or adjacent the first electrical contact 24. In this example, the second electrical contact 25 may be electrically isolated from the topside of the upper DBR mirror layer 20 by, for example, an oxide layer, and may be electrically connected to the substrate layer 6 via an electrical conductor (not specifically shown) disposed through the body 4 or on the side of body 4.

Regardless of where the second electrical contact 25 may be disposed or positioned, the first electrical contact 24 is in electrical contact only with the topside of the cap layer 22 and the second electrical contact 26 is in electrical contact only with the substrate layer 6. An electrical bias may be applied to body 4 via the first and second electrical contacts 24 and 25. This electrical bias may cause electrical current 22 (shown by dot-dashed lines in FIG. 1) to flow in the body 4 between the substrate layer 6 and the first electrical contact 24.

Details regarding the growth or fabrication of one or more of the substrate 6, the lower DBR mirror layer 8, the cavity layer 10 including the active region 12, the upper DBR mirror layer 20, and/or the first and second electrical contacts 24 and 25 are known in the art and will not be described herein for the purpose of simplicity. Moreover, other than as may be necessary for the purpose of the present description, details regarding the growth or fabrication of one or more of the light confinement layer 14, the intermediate layer 16, and/or the current confinement layer 18 are known in the art and will not be described herein for the purpose of simplicity.

In an example, the current confinement layer 18 may include an area of low resistance 26 to current flow defined by an area of high resistance 28 to current flow, whereupon current flow in the body 4 is directed or confined through the area of low resistance 26 to current flow by the area of high resistance 28 to current flow. In one non-limiting example, the area of high resistance to current flow 28 surrounds the area of low resistance to current flow 26 of the current confinement layer 18, whereupon current flow in the body 4 is directed by the area of high resistance 28 to current flow through the area of low resistance 26 to current flow.

In an example, the resistance per unit area, e.g., ohms-cm², of the area of high resistance to current flow 28 is at least 10 times greater than the resistance per unit area of the area of low resistance to current flow 26. In an example, the area of low resistance 26 to current flow may have a resistance of 10⁻³ ohm-cm² or lower and the area of high resistance 28 to current flow may have a resistance of 0.1 ohm-cm² or higher. However, this is not to be construed in a limiting sense.

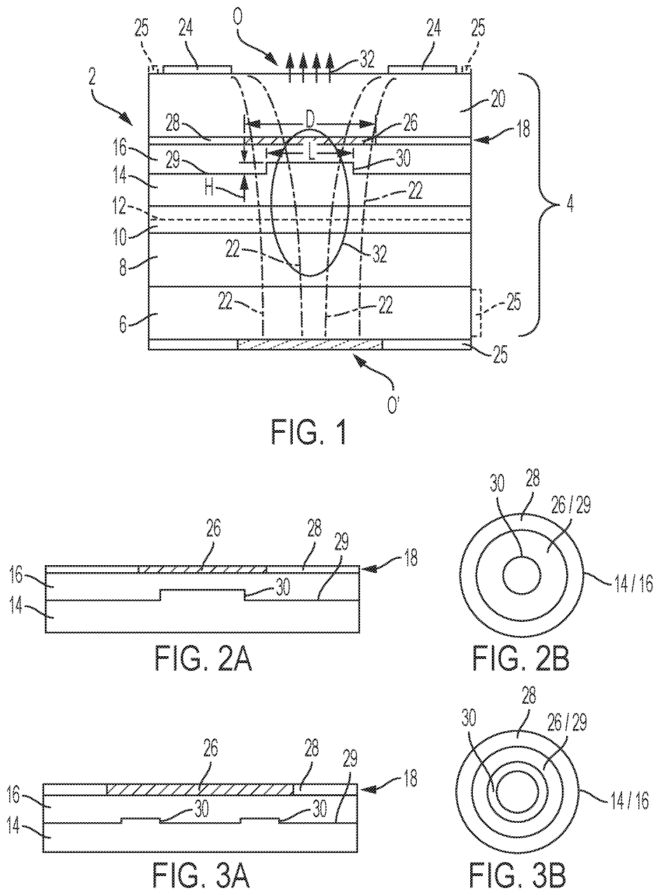

In one specific non-limiting example shown in FIGS. 1 and 2A-2B, the area of low resistance to current flow 26 may be circular shaped defined by a ring shaped inner diameter of the area of high resistance to current flow 28. However, these shapes or geometries is/are not to be construed in a limiting sense inasmuch as the use of other shapes or geometries of one or both of the areas of low resistance to current flow 26 and/or the area of high resistance to current flow 28 is/are envisioned.

In an example, the area of high resistance to current flow 28 may be formed or defined by, for example, oxidation or implantation or growth of that area of current confinement layer 18 that is to define the area of high resistance to current flow 28. In this example, the area of low resistance to current flow 26 is an area of the current confinement layer 18 that is not oxidized or implanted.

In the example VCSEL shown in FIG. 1, the light confinement layer 14 may be positioned or disposed below the intermediate layer 16 which is positioned or disposed below the current confinement layer 18. In an example, the light confinement layer 14 may include or define on a top surface 29 thereof one or more protrusions or bumps 30 positioned or disposed below and in alignment with the area of low resistance to current flow 26 of the current confinement layer 18.

In the non-limiting example shown in FIGS. 2A-2B, the protrusion or bump 30 of the light confinement layer 14 may be circular shaped and positioned in alignment or coaxial with the circular shaped area of low resistance to current flow 26 of the current confinement layer 18. However, this is not to be construed in a limiting sense since it is envisioned that the protrusion or bump 30 of the light confinement layer 14 may have any suitable and/or desirable shape or geometry (described in greater detail hereinafter) and/or the area of low resistance to current flow 26 of the current confinement layer 18 may have any suitable and/or desirable shape or geometry that may the same or different than the shape or geometry of the protrusion or bump 30 of the light confinement layer 14.

In an example, the patterning of the light confinement layer 14 produces two regions or cavities. Namely, a main region or cavity in vertical alignment with the protrusion or bump 30 and an secondary region or cavity in vertical alignment with the/those area(s) of the light confinement layer 14 that is/are not in vertical alignment the protrusion or bump 30, i.e., the arca(s) surrounding the protrusion or bump 30. The resonant wavelengths of light in the main region and the secondary region will be different and may be equal to μ0 and λ1, respectively. The difference between these wavelengths defines the effective index confinement of the light confinement layer 14 which determines the optical mode. In particular, the effective index confinement (AN) is given by:

$$Δ N / N 0 = ( λ1 - λ0 ) / λ0$$

where N0 is the effective refractive index in the main region. ΔN defines the supported lateral optical modes with a given shape or geometry of the light confinement layer 14, e.g., the maximum size of the light guiding pattern L in FIG. 1, in order to have single optical mode operation. In FIG. 1. the dimensions of the current confinement region D. i.e., the area of low resistance to current flow 26 of the current confinement layer 18, and the dimensions of the light guiding pattern L, i.e., the dimensions of the protrusion or bump 30, are independent. FIG. 1 also shows a vertical region (not marked) between D and L which may introduce an additional step index that may be taken into account during design of the VCSEL, but which is not described herein for the purpose of simplicity.

In FIG. 1, the index contrast increases with higher values of the height H of the protrusion or bump 30. In an example, a higher value of H (where H may be <μ₀/4) is desired when stronger light confinement is desired, thereby promoting higher order optical modes and/or small optical mode volumes. In the case where the dimension of H is much smaller compared to the dimension of D, the optical mode may be affected by a refractive index step between the area of low resistance 26 to current flow and the area of high resistance 28 to current flow of the current confinement layer 18.

In use of the VCSEL shown in FIG. 1, an electrical bias applied to the first and second electrical contacts 24 and 25 causes electrical current 22 to flow vertically or substantially vertically in body 4 between the substrate layer 6 and the first electrical contact 24. This flow of electrical current 22 in body 4 is directed or confined to flow through the area of low resistance 26 to current flow by the area of high resistance 28 to current flow of the current confinement layer 18. This electrical current 22 also flows through the active region 12 of the cavity layer 10 which, in response, emits light 32 (shown by the ellipse in the body 4 and by the arrows exiting the topside of the upper DBR mirror layer 20). This emitted light 32 is directed or confined, by the difference in the refractive indices of the main region of the light confinement layer 14, aligned with the protrusion or bump 30, and the secondary region of the light confinement layer 14, not aligned with the protrusion or bump 30, to flow through the area of low resistance 26 to current flow of the current confinement layer 18 and exit the top surface of the upper DBR mirror layer 20 above the protrusion or bump 30 and the area of low resistance 26 to current flow of the current confinement layer 18.

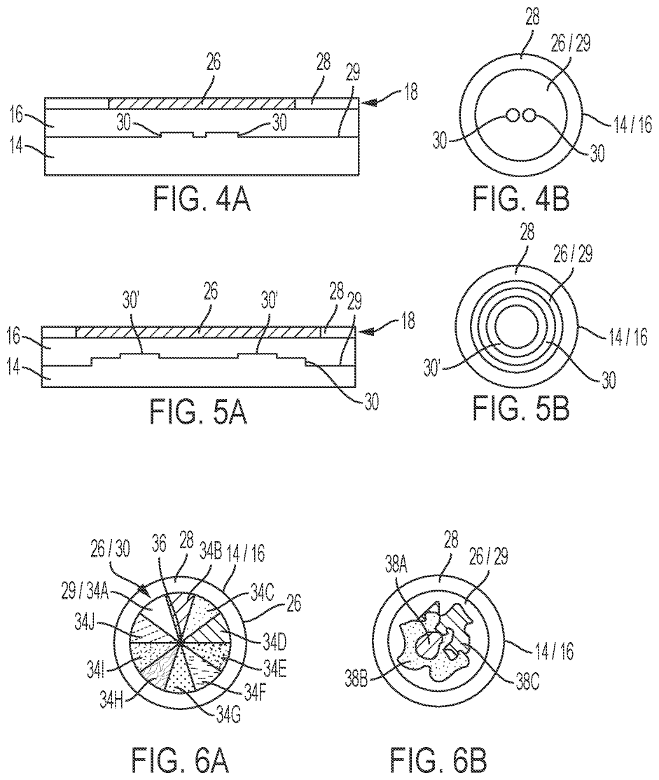

The shape or geometry of the light confinement layer 14 shown in FIGS. 2A-2B is but one non-limiting example of the shape or geometry that the light confinement layer 14, including one or more projections or bumps 30, may have. For example, as shown in FIGS. 3A-3B, the light confinement layer 14 may include a ring shaped projection or bump 30. In another example shown in FIGS. 4A-4B, the light confinement layer 14 may include at least a pair of side-by-side circular shaped projections or bumps 30. In another example shown in FIGS. 5A-5B, the light confinement layer 14 may include a circular shaped projection or bump 30 atop of which may be included a ring shaped projection or bump 30′.

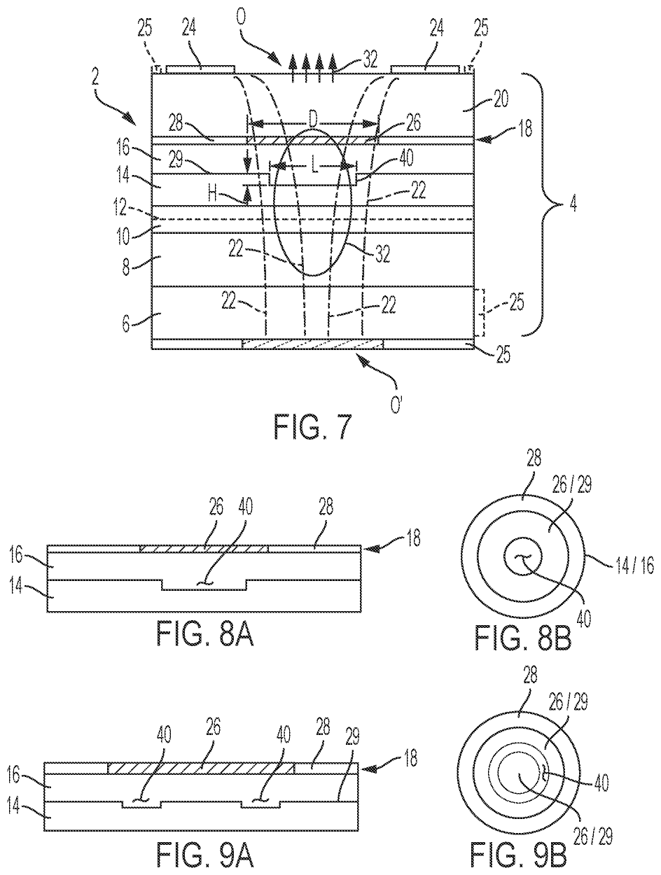

In yet another example shown in FIG. 6A, the light confinement layer 14 may include a protrusion or bump 30 in the form of circular stair-steps or a circular stair-case comprising a series of steps 34A-34J that increase or decrease in height as the steps wind around a central axis 36. The protrusion or bump 30 in the form of circular stair-steps or a circular stair-case shown in FIG. 6A may be useful for generating Orbital Angular Momentum modes (OAM) (See R. Kumar et al., IEEE Phot. Tech. Lett., vol. 33, no. 16, pp. 824-827, 2021).

In yet another example shown in FIG. 6B, the light confinement layer may include a protrusion or bump 30 having an irregular shape comprising a plurality of regions 38A-38C of different heights. The shapes or geometries the light confinement layer 14 shown in FIGS. 2A-6B, however, are not to be construed in a limiting sense since it is envisioned that the light confinement layer 14 may have any suitable and/or desirable shape or geometry deemed desirable for the VCSEL to emit light 32 having a desired shape, geometry, and/or mode for a particular application.

With reference to FIGS. 7-12B and with continuing reference to FIGS. 1-6B, other non-limiting embodiment or example VCSELs in accordance with the principles of this disclosure may, with one exception, be similar to the example VCSELs shown in FIGS. 1-6B and described above. The exception is that instead of the top surface 29 of the light confinement layer 14 including one or more protrusions or bumps 30 and/or 30′, the light confinement layer 14 of the VCSELs shown in FIGS. 7-12B may include one or more recesses or cavities 40 and/or 40′ in the top surface 29 of the light confinement layer 14. The principles of operation of the VCSELs shown in FIGS. 1-6B and described above are applicable to the principles of operation of the VCSELs shown in FIGS. 7-12B, respectively, and will not be further described herein to avoid unnecessary redundancy.

In general, the use of one or more recesses or cavities 40 in the top surface 29 of the light confinement layer 14 versus the use of one or more protrusions or bumps 30 may affect the shape, geometry, and/or mode of the light 32 exiting the topside of the upper DBR mirror layer 20. Stated differently, e.g., for the VCSELs shown in FIGS. 1 and 7, the light 32 exiting the topside of the upper DBR mirror layer 20 may have a different shape, geometry, and/or mode (uscable for different applications) due to the presence of one or more protrusions or bumps 30 and/or 30′ in the top surface 29 of the light confinement layer 14 of the VCSEL shown in FIG. 1 versus the presence of one or more recesses or cavities 40 and/or 40′ in the top surface 29 of the light confinement layer 14 of the VCSEL shown in FIG. 7.

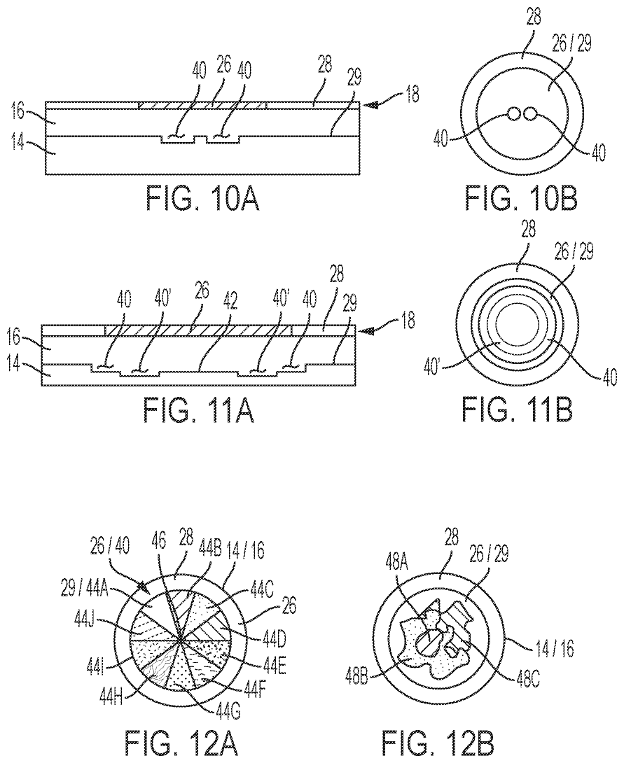

The shape or geometry of the light confinement layer 14 shown in FIGS. 8A-8B is but one non-limiting example of the shape or geometry that the light confinement layer 14 including one or more recesses or cavities 40 may have. In the example shown in FIGS. 9A-9B, the light confinement layer 14 may include a ring shaped recess or cavity 40. In another example shown in FIGS. 10A-10B, the light confinement layer 14 may include at least a pair of side-by-side circular shaped recesses or cavities 40. In another example shown in FIGS. 11A-11B, the light confinement layer 14 may include a circular shaped recess or cavity 40 including in a top surface 42 thereof a further ring shaped recess or cavity 40′.

In yet another example shown in FIG. 12A, the light confinement layer 14 may include a recess or cavity 40 in the form of circular stair-steps or a circular stair-case comprising a series of steps 44A-44J that increase or decrease in height as the steps wind around the central axis 46. The recess or cavity 40 in the form of circular stair-steps or a circular stair-case shown in FIG. 12A may be useful for generating Orbital Angular Momentum modes (OAM) (See R. Kumar et al., IEEE Phot. Tech. Lett., vol. 33, no. 16, pp. 824-827, 2021).

In yet another example shown in FIG. 12B, the light confinement layer may include a recess or cavity 40 having an irregular shape comprising a plurality of regions 48A-48C of different heights. The shapes or geometries the light confinement layer 14 shown in FIGS. 8A-12B, however, are not to be construed in a limiting sense since it is envisioned that the light confinement layer 14 may have any suitable and/or desirable shape or geometry deemed desirable for the VCSEL to emit light 32 having a desired shape, geometry, and/or mode for a particular application.

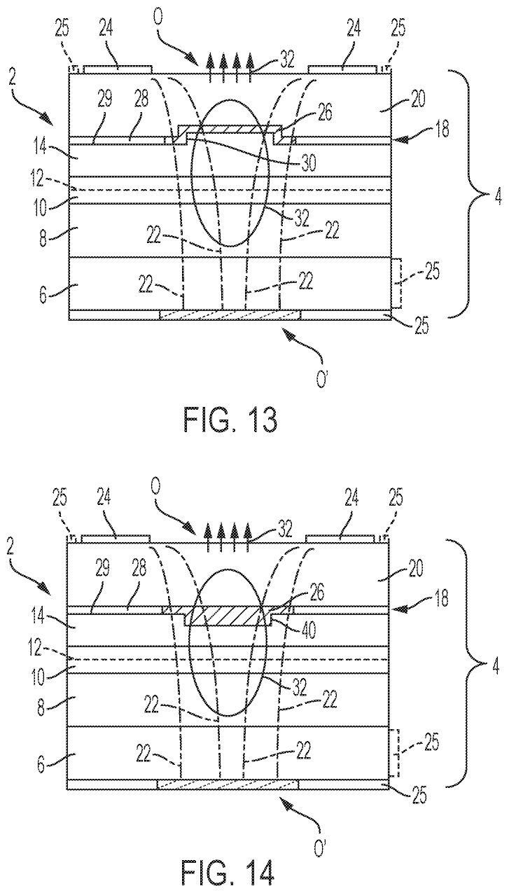

With reference to FIG. 13, another non-limiting embodiment or example VCSEL in accordance with the principles of this disclosure may, with exceptions, be similar to the example VCSEL shown in FIG. 1 and described above. One exception may include the omission or absence of the intermediate layer 16 shown in FIG. 1 in the VCSEL shown in FIG. 13. Another exception, due to the absence of the intermediate layer 16, may include the protrusion or bump 30 of the light confinement layer 14 extending or projecting into at least the current confinement layer 18, and optionally forming a corresponding protrusion or bump in the current confinement layer 18 (in particular in the area of low resistance to current flow 26 of the current confinement layer 18), and optionally extending or projecting into the bottom of the upper DBR mirror layer 20, and being surrounded by a portion of the area of low resistance to current flow 26 of the current confinement layer 18, which, in-turn is surrounded by the area of high resistance to current flow 28 of the current confinement layer 18. In an example, the topside of the upper DBR mirror layer 20 may be planar or may include a protrusion or bump (the same height or smaller) than the corresponding protrusion or bump of the current confinement layer 18.

The protrusion or bump 30 of the light confinement layer 14 of FIG. 13, may have any shape or geometry deemed suitable and/or desirable for the VCSEL to emit light 32 having a desired shape, geometry, and/or mode for a particular application. Non-limiting examples of such shapes or geometries may include the light confinement layer 14 having one or more protrusions or bumps 30 and/or 30′ as shown, for example, in any one or more of FIG. 2A-6B. Accordingly, the shape of the protrusion or bump 30 shown in FIG. 13 is not to be construed in a limiting sense.

With reference to FIG. 14, another non-limiting embodiment or example VCSEL in accordance with the principles of this disclosure may, with exceptions, be similar to the example VCSEL shown in FIG. 7 and described above. One exception may include the omission or absence of the intermediate layer 16 shown in FIG. 7 in the VCSEL shown in FIG. 14. Another exception, due to the absence of the intermediate layer 16, may include a portion of the area of low resistance to current flow 26 of the current confinement layer 18 extending or projecting into the recess or cavity 40 of the light confinement layer 14, whereupon said portion of the area of low resistance to current flow 26 is surrounded by the portion of the light confinement layer 14 that surrounds the recess or cavity 40 of the light confinement layer 14. In an example, the topside of the upper DBR mirror layer 20 may be planar or may include a recess or cavity (the same height or smaller) than the corresponding recess or cavity in the light confinement layer 14.

The recess or cavity 40 of the light confinement layer 14 of FIG. 14, may have any shape or geometry deemed suitable and/or desirable for the VCSEL to emit light 32 having a desired shape, geometry, and/or mode for a particular application. Non-limiting examples of such shapes or geometries may include the light confinement layer 14 having one or more recesses or cavities 40 and/or 40′ as shown, for example, in any one or more of FIGS. 8A-12B. Accordingly, the shape of the recess or cavity 40 shown in FIG. 14 is not to be construed in a limiting sense.

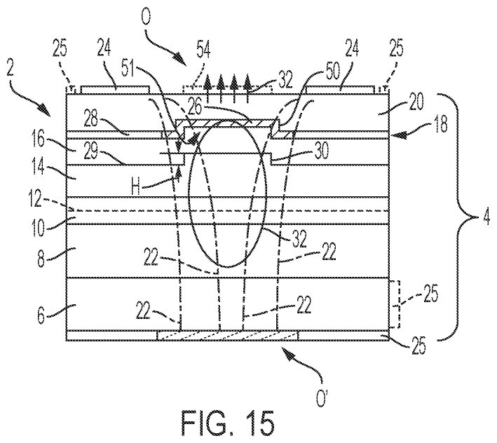

With reference to FIG. 15 and with continuing reference to FIGS. 1-6B, another non-limiting embodiment or example VCSEL in accordance with the principles of this disclosure may include, in an example, the one or more protrusions or bumps 30, 30′, 34 and/or 38 on the top surface 29 of the light confinement layer 14 may result in one or more corresponding protrusions or bumps (not shown in FIGS. 1-6B for the purpose of simplicity) forming on some or all of the following layers during the growth thereof over the light confinement layer 14: protrusion or bump 51 of the intermediate layer 16, protrusion or bump 50 of the current confinement layer 18 (in particular the area of low resistance to current flow 26 of the current confinement layer 18), and/or protrusion or bump 54 (shown in phantom) of the upper DBR mirror layer 20. In another example, the intermediate layer 16, the current confinement layer 18, and the upper DBR mirror layer 20 may have progressively smaller (relative to height H) protrusions or bumps above the one or more protrusions or bumps 30, 30′, 34 and/or 38 on the top surface 29 of the light confinement layer 14, including, in an example, the topside of the upper DBR mirror layer 20 being planar and/or, optionally, the top surface of the current confinement layer 18 being planar. However, these examples are not to be construed in a limiting sense since the topside surface of each layer above the protrusions or bumps 30, 30′, 34 and/or 38 on the top surface 29 of the light confinement layer 14 may have a protrusion or bump or may be planar as shown in FIGS. 1, 2A, 3A, 4A, and 5A.

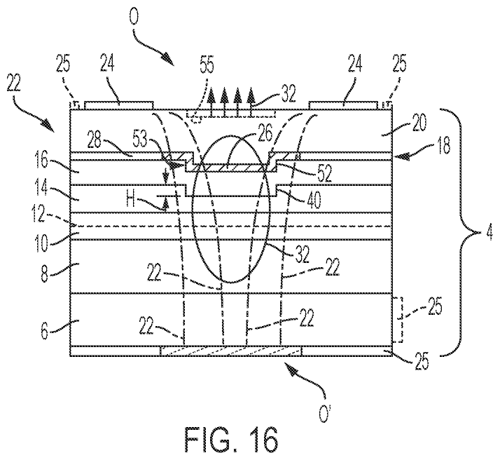

With reference to FIG. 16 and with continuing reference to FIGS. 7-12B, another non-limiting embodiment or example VCSEL in accordance with the principles of this disclosure may include, in an example, the one or more recesses or cavities 40 and/or 40′ on the top surface 29 of the light confinement layer 14 may result in one or more corresponding recesses or cavities 40 and/or 40′ (not shown in FIGS. 7-12B for the purpose of simplicity) forming in some or all of the following layers during the growth thereof over the light confinement layer 14: recess or cavity 53 of the intermediate layer 16, recess or cavity 52 of the current confinement layer 18 (in particular the area of low resistance to current flow 26 of the current confinement layer 18), and/or recess or cavity 55 (shown in phantom) of the upper DBR mirror layer 20. In another example, the intermediate layer 16, the current confinement layer 18, and the upper DBR mirror layer 20 may have progressively smaller (relative to height H) recesses or cavities above the one or more recesses or cavities 40 and/or 40′ in the top surface 29 of the light confinement layer 14, including, in an example, the topside of the upper DBR mirror layer 20 being planar and/or, optionally, the top surface of the current confinement layer 18 being planar. However, these examples are not to construed in a limiting sense since the topside surface of each layer above the one or more recesses or cavities 40 and/or 40′ in the top surface 29 of the light confinement layer 14 may have a recess or cavity or may be planar as shown in FIGS. 7, 8A, 9A, 10A, and 11A.

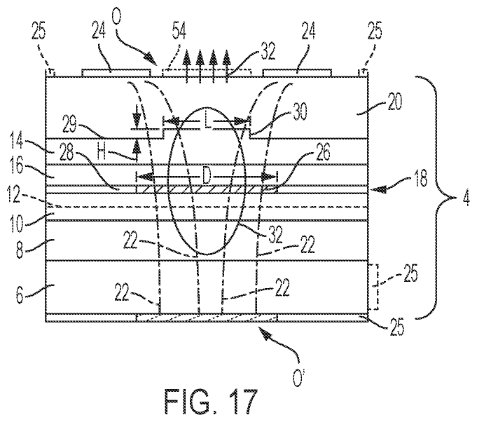

With reference to FIG. 17, another non-limiting embodiment or example VCSEL in accordance with the principles of this disclosure is similar to the example VCSEL shown in FIG. 1 except that the positions of the light confinement layer 14 and the current confinement layer 18 in FIG. 1 are reversed in FIG. 17, whereupon, in FIG. 17, the light confinement layer 14 is above the intermediate layer 16 which is above current confinement layer 18. As shown in FIG. 17, the topside of the upper DBR mirror layer 20 above the protrusion or bump 30 of the light confinement layer 14 may be planar (as shown by solid line) or may include an optional protrusion or bump 54 (shown in phantom) above the protrusion or bump 30 of the light confinement layer 14 that is due to the growth of the upper DBR mirror layer 20 atop of the light confinement layer 14 including the protrusion or bump 30.

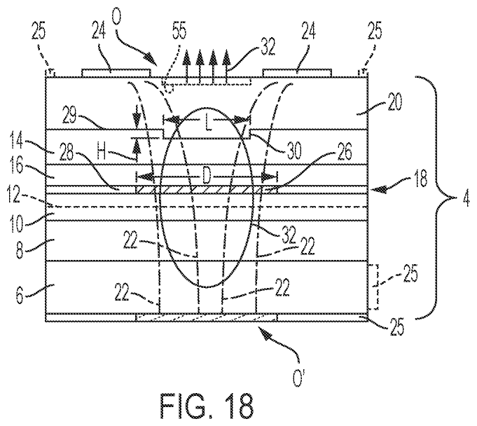

With reference to FIG. 18, another non-limiting embodiment or example VCSEL in accordance with the principles of this disclosure is similar to the example VCSEL shown in FIG. 7 except that the positions of the light confinement layer 14 and the current confinement layer 18 in FIG. 7 are reversed in FIG. 18, whereupon, in FIG. 18, the light confinement layer 14 is above the intermediate layer 16 which is above current confinement layer 18. As shown in FIG. 18, the topside of the upper DBR mirror layer 20 above the recess or cavity 40 of the light confinement layer 14 may be planar (as shown by solid line) or may include an optional recess or cavity 55 (shown in phantom) above the recess or cavity 40 of the light confinement layer 14 that is due to the growth of the upper DBR mirror layer 20 atop of the light confinement layer 14 including the recess or cavity 40.

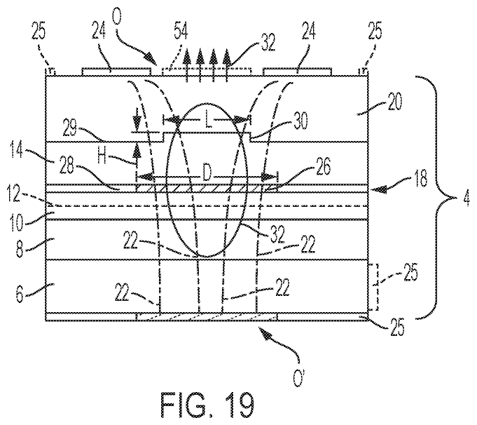

With reference to FIG. 19, another non-limiting embodiment or example VCSEL in accordance with the principles of this disclosure is similar to the example VCSEL shown in FIG. 17 except that the intermediate layer 16 is omitted, whereupon the topside of the current confinement layer 18 is in contact with the bottom side of the light confinement layer 14.

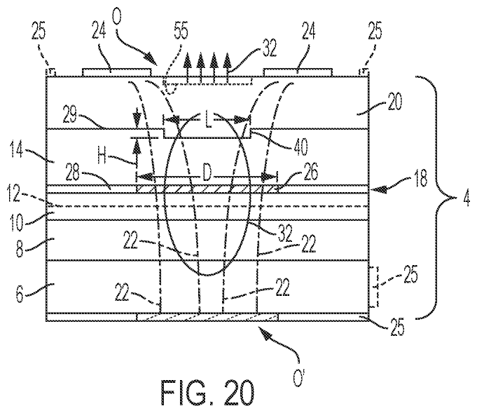

With reference to FIG. 20, another non-limiting embodiment or example VCSEL in accordance with the principles of this disclosure is similar to the example VCSEL shown in FIG. 18 except that the intermediate layer 16 is omitted, whereupon the topside of the current confinement layer 18 is in contact with the bottom side of the light confinement layer 14.

Finally, herein, light 32 is described and illustrated in the figures as exiting upwardly from the topside of the upper DBR mirror layer 20. However, in an example, it is envisioned that each non-limiting embodiment or example VCSEL illustrated and described herein may be modified such that the upper DBR layer 20 has a higher reflectivity than the lower DBR layer 8 whereupon light 32 may be reflected by the upper DBR layer 20 through the stack of semiconductor layers 4 and exit downwardly through the substrate layer 6, which remains at the bottom of the stack of semiconductor layers 4.

In this example, the second electrical contact 25 may be positioned in electrical contact with the bottom side of the substrate layer 6 and may be formed with an opening O′, shown in phantom in FIGS. 1, 7, and 13-20, like the opening O shown in these figures, to allow light 32 passing downwardly through the substrate layer 6 to exit the bottom side of the substrate layer 6 through the opening O′. In an example, the first electrical contact 24 may be positioned on the topside of the stack of semiconductor layers 4, e.g., on the topside of the upper DBR mirror layer 20, and its opening O may be omitted.

In another example, a second electrical contact 25 may be positioned, as shown in phantom in FIGS. 1, 7, and 13-20, on the side of the body 2 in electrical contact with substrate 6. In yet another example, the second electrical contact 25 may be positioned, as shown in phantom in FIGS. 1, 7, and 13-20, on the topside of the stack of semiconductor layers 4, i.e. on the topside of the upper DBR mirror layer 20, proximate or adjacent the first electrical contact 24. In this latter example, the second electrical contact 25 may be electrically isolated from the topside of the stack of semiconductor layers 4 by, for example, an oxide layer, and may be electrically connected to the substrate layer 6 via an electrical conductor (not specifically shown) disposed through the body 4 or on the side of body 4.

Although the disclosure has been described in detail for the purpose of illustration based on what is currently considered to be the most practical and preferred examples, it is to be understood that such detail is solely for that purpose and that the disclosure is not limited to the disclosed examples, but, on the contrary, is intended to cover modifications and equivalent arrangements that are within the spirit and scope of the appended claims. For example, it is to be understood that the present disclosure contemplates that, to the extent possible, one or more features of any example may be combined with one or more features of any other example.

1. A vertical cavity surface-emitting laser (VCSEL) comprising:
a body comprising a vertical stack of semiconductor layers one on top of the other, wherein the stack of semiconductor layers comprises:
a current confinement layer including an area of low resistance to current flow defined by an area of high resistance to current flow, whereupon vertical current flow in the stack of semiconductor layers is directed by the area of high resistance to current flow of the current confinement layer through the area of low resistance to current flow of the current confinement layer; and
a light confinement layer disposed below or above the current confinement layer, the light confinement layer including a protrusion or a recess disposed respectively below or above the area of low resistance to current flow of the current confinement layer.

2. The VCSEL of claim 1, wherein the stack of semiconductor layers include in order:
a first Distributed Bragg Reflection (DBR) mirror layer;
a cavity layer including an active region;
one of:
(a) the light confinement layer and the current confinement layer; or
(b) the current confinement layer and the light confinement layer; and
an second DBR mirror layer.

3. The VCSEL of claim 2, wherein the stack of semiconductor layers further includes:
a substrate layer below the stack of semiconductor layers;
a first contact on a side of the stack of semiconductor layers opposite the substrate layer; and
a second contact on a side of the substrate layer opposite the stack of semiconductor layers, or on a side of the body, or on the side of the stack of semiconductor layers opposite the substrate layer, wherein the first contact is in electrical contact only with the side of the stack of semiconductor layers opposite the substrate layer and the second contact is in electrical contact only with the side of the substrate layer opposite the stack of semiconductor layers.

4. The VCSEL of claim 1, wherein the area of high resistance to current flow of the current confinement layer surrounds the area of low resistance to current flow of the current confinement layer.

5. The VCSEL of claim 4, wherein the protrusion or the recess of the light confinement layer is positioned in alignment with the area of low resistance to current flow of the current confinement layer.

6. The VCSEL of claim 5, wherein the area of low resistance to current flow of the current confinement layer is circular shaped.

7. The VCSEL of claim 6, wherein the protrusion or the recess of the light confinement layer is coaxial with the circular shaped current confinement layer.

8. The VCSEL of claim 5, wherein the protrusion or the recess of the light confinement layer is round or circular or ring shaped.

9. The VCSEL of claim 5, wherein:
the protrusion of the light confinement layer includes a ring shaped protrusion atop of a round or circular protrusion or recess; and
the recess of the light confinement layer includes a ring shaped protrusion or recess formed in a round or circular protrusion or recess.

10. The VCSEL of claim 5, wherein the protrusion or the recess of the light confinement layer includes a pair of protrusions or recesses.

11. The VCSEL of claim 1, wherein the current confinement layer comprises an oxidized or implanted semiconductor layer.

12. The VCSEL of claim 5, wherein the protrusion or the recess of the light confinement layer includes circular stair-steps comprising a series of steps that increase or decrease in height as the steps wind around a central axis.

13. The VCSEL of claim 5, wherein the protrusion or the recess of the light confinement layer is irregular shaped and includes a plurality of regions of different heights.

14. The VCSEL of claim 2, further comprising an intermediate layer between the current confinement layer and the light confinement layer.

15. The VCSEL of claim 14, wherein the stack of semiconductor layers further includes:
a substrate layer below the stack of semiconductor layers;
a first contact on a side of the stack of semiconductor layers opposite the substrate layer; and
a second contact on a side of the substrate layer opposite the stack of semiconductor layers, or on a side of the body, or on the side of the stack of semiconductor layers opposite the substrate layer, wherein the first contact is in electrical contact only with the side of the stack of semiconductor layers opposite the substrate layer and the second contact is in electrical contact only with the side of the substrate layer opposite the stack of semiconductor layers.

16. The VCSEL of claim 14, wherein the area of high resistance to current flow of the current confinement layer surrounds the area of low resistance to current flow of the current confinement layer.

17. The VCSEL of claim 15, wherein the protrusion or the recess of the light confinement layer is positioned in alignment with the area of low resistance to current flow of the current confinement layer.

18. The VCSEL of claim 17, wherein the area of low resistance to current flow of the current confinement layer is circular shaped.

19. The VCSEL of claim 18, wherein the protrusion or the recess of the light confinement layer is coaxial with the circular shaped current confinement layer.

20. The VCSEL of claim 17, wherein the protrusion or the recess of the light confinement layer is round or circular or ring shaped.

21. The VCSEL of claim 17, wherein the protrusion or the recess of the light confinement layer includes a ring shaped protrusion or recess atop of or in a round or circular protrusion or recess.

22. The VCSEL of claim 17, wherein the protrusion or the recess of the light confinement layer includes a pair of protrusions or recesses.

23. The VCSEL of claim 17, wherein the protrusion or the recess of the light confinement layer includes circular stair-steps comprising a series of steps that increase or decrease in height as the steps wind around a central axis.

24. The VCSEL of claim 17, wherein the protrusion or the recess of the light confinement layer is irregular shaped and includes a plurality of regions of different heights.

25. The VCSEL of claim 16, wherein:
when the light confinement layer includes the protrusion, the intermediate layer also includes a protrusion aligned with the protrusion of the light confinement layer; and
the protrusion of the intermediate layer projects into a space surrounded by the area of high resistance to current flow of the current confinement layer.

26. The VCSEL of claim 12, wherein the area of high resistance to current flow of the current confinement layer comprises an oxidized or implanted semiconductor layer.

27. The VCSEL of claim 14, wherein the area of high resistance to current flow of the current confinement layer comprises an oxidized or implanted semiconductor layer.
